(19) United States
(12) Patent Application Publication
(10) Pub. No.: US 2006/0284240 A1
(43) Pub. Date: Dec. 21, 2006

(54) Structure of a non-volatile memory device and operation method

(76) Inventors: Tsung-Min Hsieh, Miaoli City (TW); Chien-Hsing Lee, Jhubei City (TW); Chin-Hsi Lin, Hsinchu (TW); Jhyy-Cheng Liou, Jhubei City (TW)

Correspondence Address: J.C. Patents, Suite 250, 4 Venture, Irvine, CA, 92618, US

(21) Appl. No.: 11/473,578

(22) Filed: Jun. 22, 2006

Related U.S. Application Data
(63) Continuation-in-part of application No. 11/154,378, filed on Jun. 15, 2005.

(51) Int. Cl. H01L 29/788

(52) U.S. Cl. 257/315

(57) ABSTRACT

A nonvolatile memory device includes composite gate structures formed on a substrate in series along a bit line direction. The composite gate structure has a first storage gate structure, a second storage gate structure, and a selection gate between the two storage gate structures. Each of the composite gate structures is respectively coupled to two world line connection terminals at the two storage gate structures and a selection terminal at the selection gate. Each of the storage gate structures corresponds to a memory bit cell. Multiple doped regions are in the substrate between the composite gate structures. A first selection doped region are formed in the substrate and coupled between a BL connection terminal and a first edge one of the composite gate structure. A second selection doped region is formed in the substrate and coupled between a second edge one of the composite gate structures and a voltage terminal.

### CROSS-REFERENCE TO RELATED APPLICATION

This application is a continuation-in-part of a prior application Ser. No. 11/154,378, filed Jun. 15, 2005. All disclosures are incorporated herewith by reference.

### BACKGROUND OF THE INVENTION

1. Field of Invention

The present invention relates to memory device. More particularly, the present invention relates to a technology for fabricating the non-volatile memory device.

2. Description of Related Art

The non-volatile memory, such as flash memory device, allows multiple times erase and program operation inside system. As a result, flash memory is suitable to many of advance hand-held digital equipments, including solid state disks, cellar phones, digital cameras, digital movie cameras, digital voice recorders, and PDA, that are demanding a low-cost, high-density, low-power-consumption, highly reliable file memory.

Conventional technology is a NAND type flash memory with memory transistors connected in series by way of N+ impurity diffusion layer. FIG. 1A is a cross-sectional view, illustrating the semiconductor structure of the conventional NAND flash memory. In FIG. 1A, the substrate 100 usually has logic device region and the memory device region with the doped well with desired conductive type. In the following descriptions, only the memory region is described. The substrate for example has the N-type doped well DNW 100 and then a p-type doped well TPW 102 is formed within the DNW 100. The string of NAND memory cells are then formed on the P-type well 102. Each of the memory cells 0, 1, 2, . . . , n−1 has the gate structure 112, including the floating gate and the control gate, as known by the ordinary skilled artisans. The source/drain (S/D) doped region 104 is formed in the substrate 100 at each side of the gate structure. Two selection transistors 114 and 116 are coupled at the beginning and the end of the memory string. The selection transistor includes the gate electrode and the S/D regions at each side of the gate electrode. The S/D region 106 of the first selection transistor 114 is coupled to the bit line (BL) voltage while the S/D region 110 of the last selection transistor 116 is coupled to a voltage VS.

The operation of the NAND type memory is described. FIGS. 1B-1D are the operations of program, erase, and read based on the structure in FIG. 1A. In FIG. 1B, for example, the cell 0 is to be programmed. The bit line voltage is set to ground GND and applied to the S/D region 106. The S/D region 110 of the selection transistor 116 is also set to a ground voltage GND. The gate electrode of the selection transistor 114 set to a trigger voltage VCC to turn on the transistor, so as to allow the bit line voltage to pass to the doped region 105, which also serves as the S/D region 104 of the cell 0. The other cells 1, 2, . . . , n−1 are also turned on by applying a voltage ½ VPP, such as 10 V on the gate electrode, so as to pass the ground voltage at the S/D region 110 to the cell 1. The gate electrode of the cell 0 is applied with the voltage of VPP, such as 20 V. As a result, electrons are injected into the floating gate of the gate structure 112 to program the cell 0.

In FIG. 1C, when the erase operation is performed, all of the gate structures 112 are set to ground voltage GND. The selection transistors are also turned on but the S/D regions are at floating state. However, the p-type well 102 is applied a high voltage VPP. As a result, the electrons stored in the floating gate of the gate structure are driven to the substrate, and then the stored information in any one of the memory cells is erased.

In FIG. 1D, when the read operation is performed, in which the memory cell 0 is for example to be read, the gate structures 112 of the memory cells 1, 2, . . . , n−1 are applied to a pass voltage Vpass, such as 7V, so that the ground voltage at the S/D region 110 is passed to the adjacent S/D region 104 of the memory cell 0. The control gate of the gate structure 112 of the memory cell 0 is applied the ground voltage GND. However, the floating gate still carries positive voltage to turn on the memory cell 0 due to electrons being pulled out of the floating gate, if this memory cell has currently been programmed to “1”. The p-type well 102 is applied a ground voltage of GND. The BL line at the S/D region 106 then senses the conductive state of this memory string.

For the conventional NAND memory cell, it at least has several disadvantages. For example, device operation of this memory cell adopts channel FN programming and erase. The disadvantages includes, for example, the program speed is lower than that with channel hot electron. Also and, it needs an extra selection transistor on source side. In addition, the cell gate between two N+ impurity layers is difficult to shrink due to short channel effect. In brief, the disadvantages includes the low programming speed due to FN tunneling, the junction to junction leak for the programmed cell, and the extra selection transistor on source side of the for programming.

### SUMMARY OF THE INVENTION

The invention provides a novel non-volatile memory device, such as the flash memory device, the foregoing conventional disadvantages can at least be significantly solved. As a result, the operation speed can be effectively improved and the current leakage can be reduced. Also and, only one doped region is needed for one memory cell, so that the device size can be effectively reduced.

The present invention provides a nonvolatile memory device, which includes composite gate structures formed on a substrate in series along a bit line (BL) direction. Each of the composite gate structures comprises a first storage gate structure, a second storage gate structure, a selection gate between the two storage gate structures, and an insulating layer for isolating the various gates. Each of the storage gate structures corresponds to a memory bit cell. A plurality of doped regions is in the substrate between the composite gate structures. A first selection doped region is formed in the substrate, coupled between a first BL connection terminal and a first edge one of the composite gate structures. A second selection doped region is formed in the substrate, coupled between a second BL connection terminal and a second edge one of the composite gate structures. Each of the storage gate structures of the composite gate structures includes a charge storage layer over the substrate and a control gate over the charge storage layer.

According to the further aspect of the invention, the two control gates of the two storage gate structures together are an integrated gate layer also over the selection gate, so that the two control gates are electrically connected.

According to the further aspect of the invention, the two control gates of the two storage gate structures are structurally separated at both sides of the selection gate.

The present invention further provides a semiconductor structure of dual-bit memory cell, comprising a first storage gate structure over a substrate; a second storage gate structure over the substrate; a selection gate over the substrate between the first and the second storage gate structures; a first doped region, in the substrate at an outer side of the first storage gate structure; and a second doped region, in the substrate at an outer side of the second storage gate structure. The first storage gate structure and the second storage gate structure are a stack gate structure including a charge storage layer and a control gate over the charge storage layer.

The present invention further provides an operation method of the foregoing nonvolatile memory device, comprising applying a set of reading voltages on the composite gate structures, the first selection doped region and the second selection doped region, for a read operation on a selected reading cell. Then, a set of programming voltages is applied on the composite gate structures, the first selection doped region and the second selection doped region, for a program operation on a selected programming cell. A set of erasing voltages is applied on the composite gate structures, the first selection doped region and the second selection doped region, for an erase operation on a selected erasing cell.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view, schematically illustrating the semiconductor structure of a conventional NAND type nonvolatile memory device.

FIGS. 1B-1D are the drawings, schematically illustrating the operations of read, program, and erase with respect to the structure in FIG. 1A.

FIGS. 2A-2B are circuit drawings, schematically illustrating an array structure of the nonvolatile memory device, according to an embodiment of the invention.

FIGS. 3A-3B are circuit drawings, schematically illustrating an array structure of the nonvolatile memory device, according to another embodiment of the invention.

FIGS. 4A-4B and 5A-5B are cross-sectional views, schematically illustrating the various semiconductor structures of a NAND type nonvolatile memory device, according the embodiment of the invention.

FIGS. 6 and 7 are top-view drawings, schematically illustrating a layout of the nonvolatile memory devices as shown in FIGS. 4-5.

FIG. 8A is the drawing, schematically illustrating the program operations, according to the embodiment of the invention.

FIG. 8B is the drawing, schematically illustrating the read operations, according to the embodiment of the invention.

FIG. 8C is the drawing, schematically illustrating the erase operations, according to the embodiment of the invention.

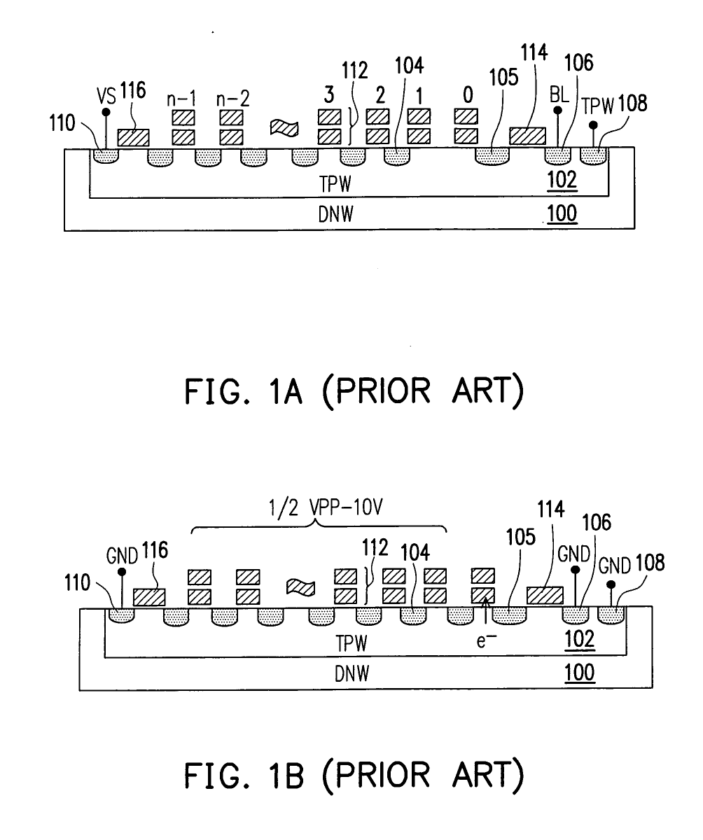

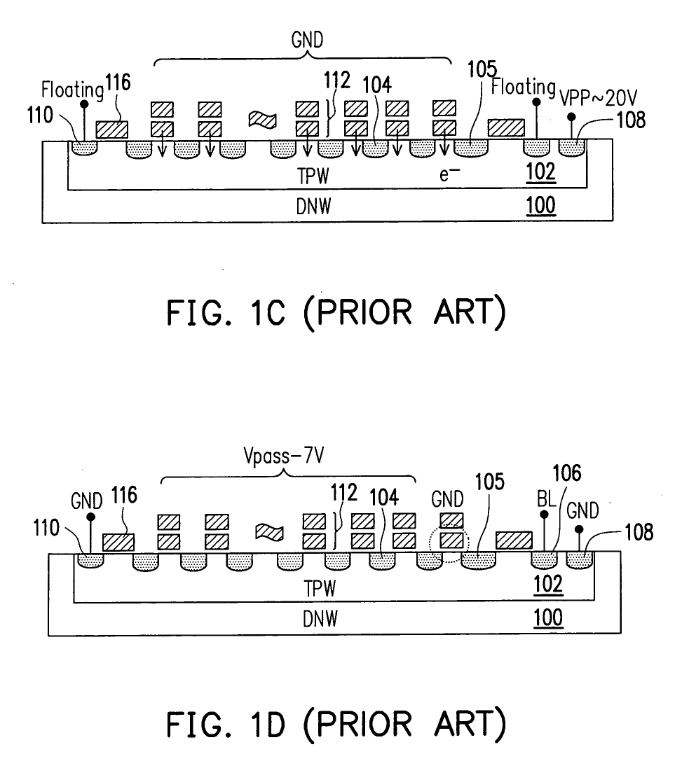

### DESCRIPTION OF THE PREFERRED EMBODIMENTS

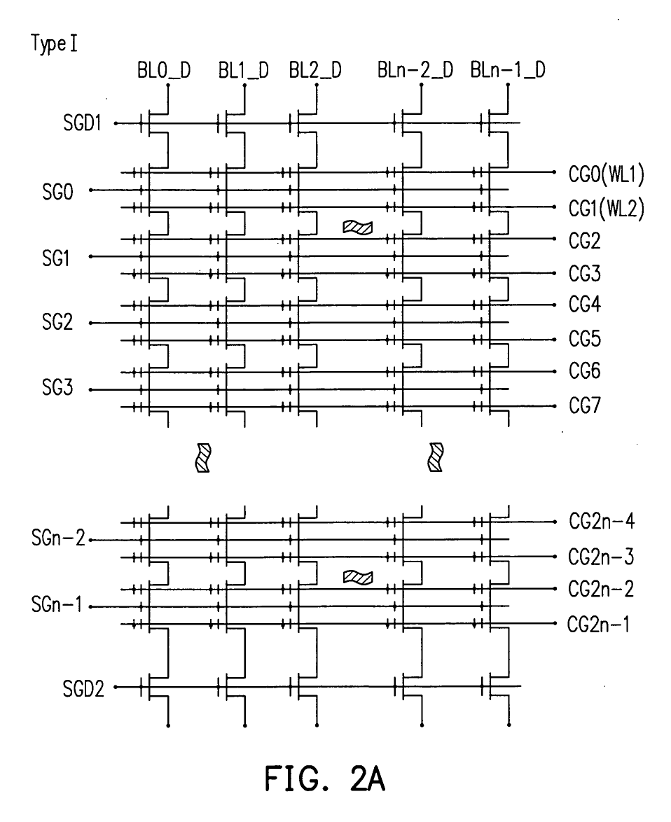

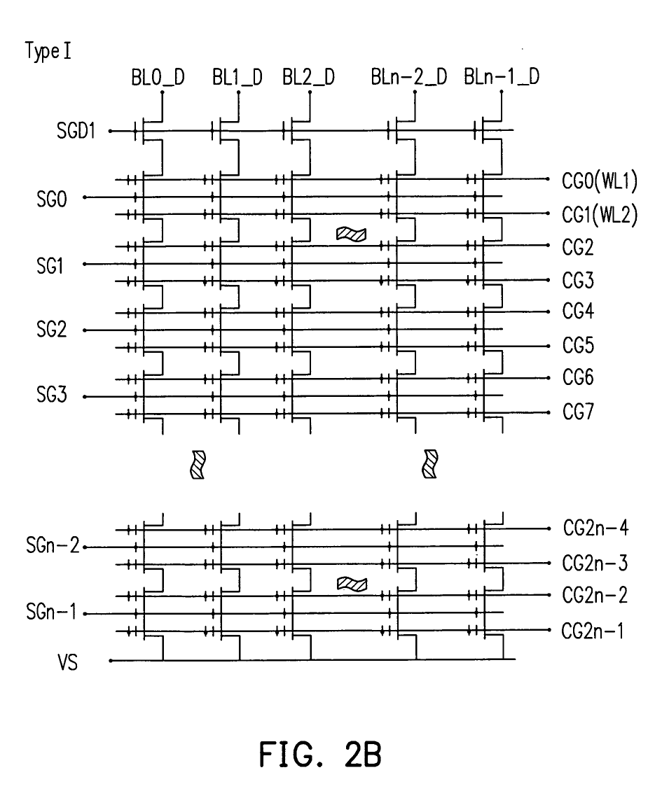

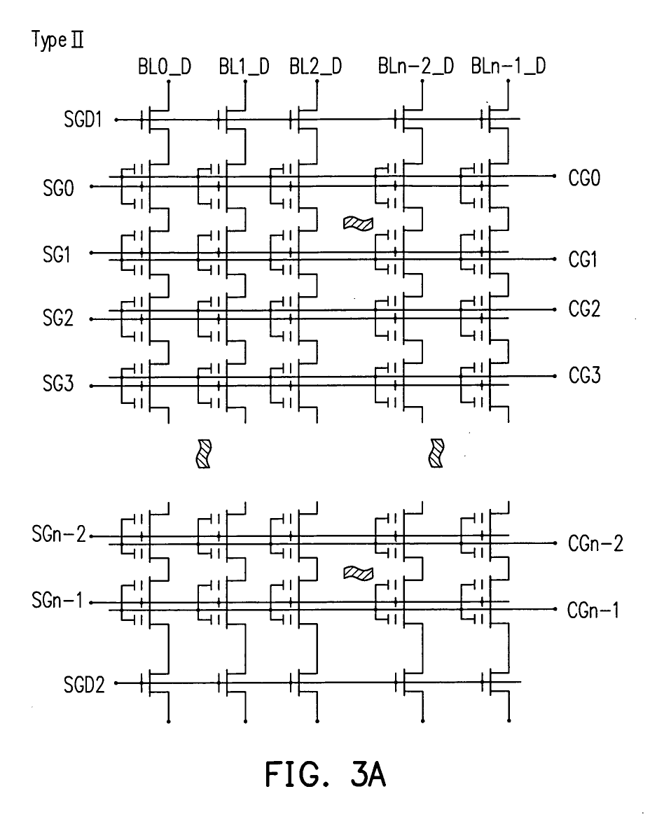

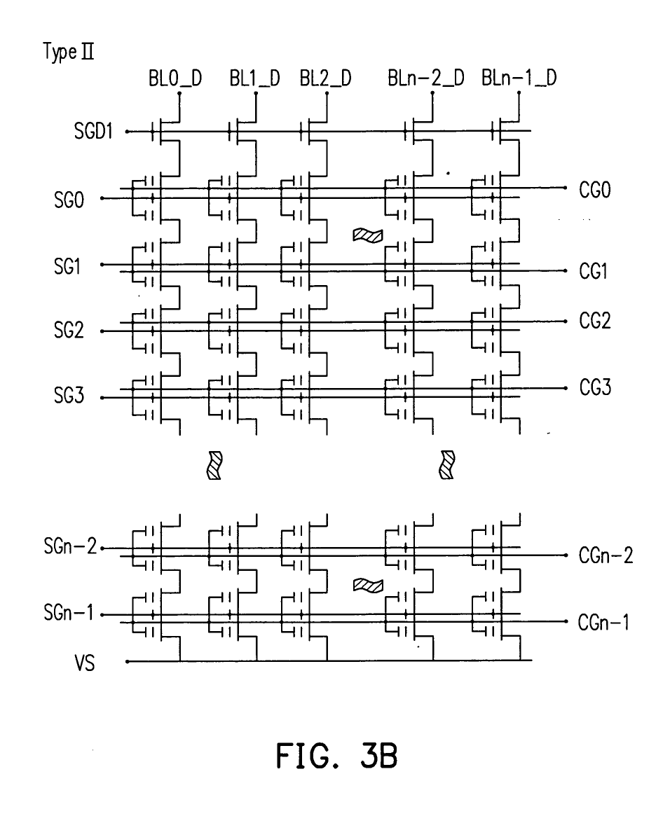

The invention is directed a novel volatile memory device. In order to perform good reliability, the structure of the memory array is proposed, as shown in FIGS. 2A-2B and FIGS. 3A-3B. About the general properties of the invention, the novel memory device is an NAND Type array architecture with memory transistors connected in series by way of n+impurity layer and select gate in turn along the bit line. The advantage of this cell compared to conventional NAND memory device is that the source side hot electron can be adopted in this novel nonvolatile memory device. The source side hot electron program can provide very high program speed and low program current. The novel memory device can has one selection transistor on BL side or two selection transistors on both side of memory array. It is easy to shrink the cell gate due to only one impurity layer for one cell, while there are two impurity layers on both sides of cell gate for conventional NAND flash.

FIGS. 2A-2B are circuit drawings, schematically illustrating an array structure of the nonvolatile memory device, according to an embodiment of the invention. In FIG. 2A, the memory cell employ a stack gate as the storage gate structure for storing the information, in which the stack gate usually includes, for example, the charge storage layer for storing information and the control gate on the charge storage layer for controlling the cell to drive electron in or out from the charge storage layer. The charge storage layer can include a proper material for storing charges. The material includes, for example, nitride layer to be SONOS (silicon-oxide-nitride-oxide-silicon) cell. Further, the nitride layer, such as SiN layer, of the memory cell can be replaced to any dielectric layer that can capture or store electron and hole during program and erase operation, like Si rich SiN, tantalum oxide (Ta₂O₅), Aluminum oxide (Al₂O₃), or even like nano-crystal Silicon. The charge storage layer preferable is a stacked structure, in which a charge trapping layer is between a bottom oxide layer and a top oxide layer. The control gates are coupled to the corresponding word lines. For example, the control gate 0 (CG0) is coupled to the word line 1 (WL1) and the control gate 1 (CG1) is coupled to the word line 2 (WL2). In the invention, the adjacent two memory bit cells are implemented with a selection gate, such as SG1 with respect to CG0 and CG1, so that a dual-bit memory cell can be formed. The desired source/drain (S/D) regions can be applied to the bit line terminals BL0_D, BL1-D, . . . BLn−1_D in a memory block, and the source terminal at the other end of the bit line terminals. The S/D regions are passed to the selected cell, so as to form a result equivalent to a single MOS memory cell with a composite gate structure. The select gate (SG) is used with the control gate to access one bit of the memory cell, according to the current direction in the bit line. The equivalent semiconductor structure and operations will be described later. In FIG. 2A, it is just an example of the invention. Alternatively, for example, one of the selection transistor, such as SGD2 in FIG. 2A, can be omitted. Instead, a power terminal can be directly applied to the S/D region of the edge one of the composite gate.

FIGS. 3A-3B circuit drawings, schematically illustrating an array structure of the nonvolatile memory device, according to another embodiment of the invention. In FIG. 3A, it is similar to the circuit structure in FIG. 2A but the two control gates in one composite gate structure are connected together. Therefore, for one dual-bit cell, only one control gate (CG) is needed in control. The equivalent semiconductor structure and operations will be described later. Likewise, FIG. 3B shown another example by omitting one selection transistor.

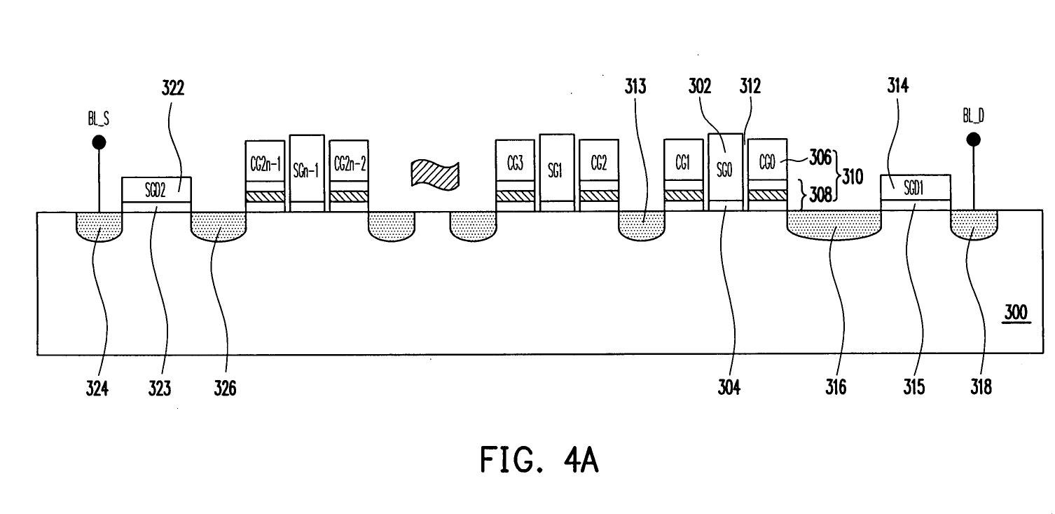

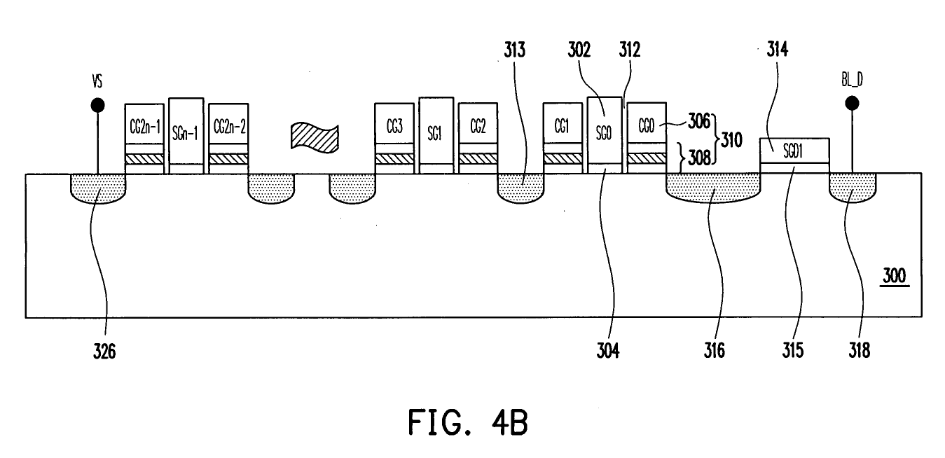

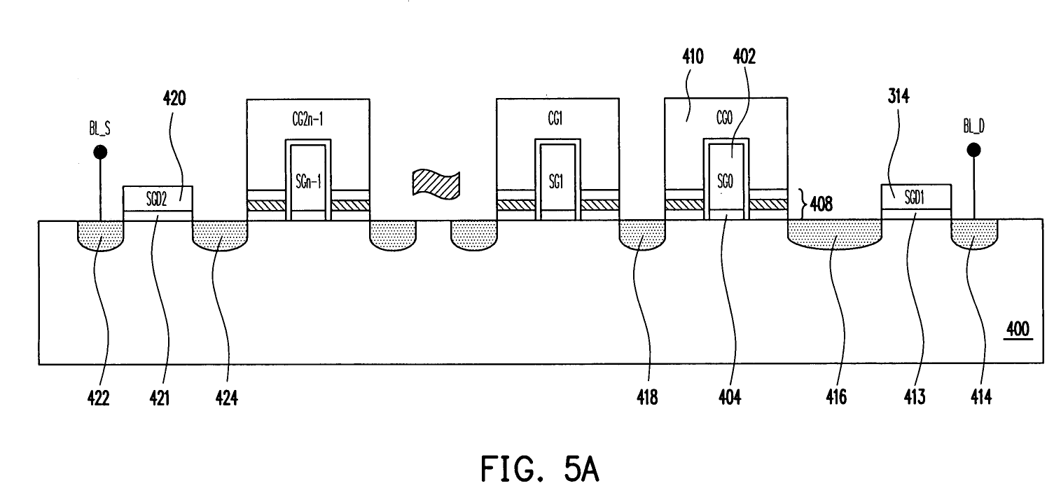

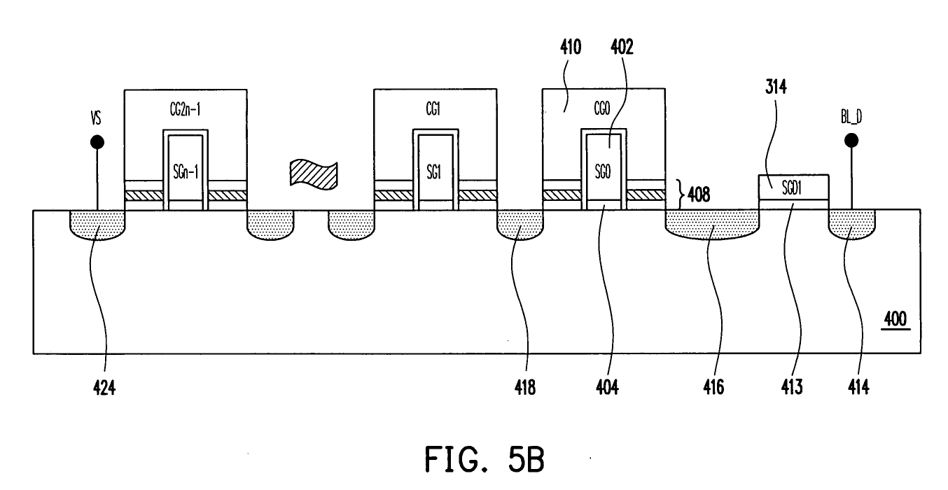

FIGS. 4A-4B and 5A-5B are cross-sectional views, schematically illustrating the various semiconductor structures of a NAND type nonvolatile memory device, according the embodiment of the invention. In FIG. 4A, the semiconductor structure alone one bit line is equivalent to FIG. 2A. On a substrate 300, the composite gate structure includes two storage gate structures 310 and a select gate structure having a select gate 302 and a gate dielectric layer 304. The two storage gate structures 310 are at both sides of the select gate structure and are isolated by the dielectric layer 312. The storage gate structure 310 includes a control gate 306 and a charge storage layer 308. The charge storage layer 308, as mentioned above, can include for example a bottom dielectric layer, a charge trapping layer, and a top dielectric layer. The charge storage layer 308 can have various options, which are described one by one here, but can be known by the one with ordinary skill in the art.

A doped region 313, serving as S/D region, is formed in the substrate between the composite gate structures. For the first-edge one of the composite gate structures, such as the one with control gate CG0, is connected with a selection transistor, having the select gate 314, a gate dielectric layer 315, and the S/D regions 316 and 318. The S/D region 316 may be commonly used with the first-edge one of the composite gate structures. Likewise, the second-edge one of the composite gate structures, such as the one with control gate CG 2n−1, is connected with another selection transistor, having the select gate 322, a gate dielectric layer 323, and the S/D regions 324 and 326. The S/D region 326 may be commonly used with the second-edge one of the composite gate structures. For the transistor string, the two selection transistors are symmetric, and can be alternatively serve as the drain region, and the source region, according to the applied voltage for producing a current direction. In FIG. 4A, the doped region 318 of one selection transistor serves as a bit line terminal BL_D, which can be applied with a drain voltage. The other doped region 324 of the other selection transistor serves as a bit line terminal BL_S, which can be applied with a drain voltage. According to the actual operation to access one bit of the dual-bit memory cell, the current direction, caused by the source voltage and the drain voltage, determines the desired bit. As previous description, FIG. 4B shows the schematic semiconductor structure for the alternative situation in omitting one selection transistor. The S/D region 326 is directly coupled to a power terminal VS.

In FIG. 5A, the composite gate structure is similar to the composite gate structure in FIG. 4A but the two control gates are connected together. The composite gate structure includes the select gate structure and two storage gate structures. Taking the first-edge one of the composite gate structure as the example, the select gate structure include a select gate 402 and a gate dielectric layer 404 on the substrate 400. Each of the two storage gate structures includes the contrail gate 410 and the charge storage layer 408. The charge storage layer 408 is similar to the charge storage layer 310 in FIG. 4A. However, preferably, the two control gates are connected together, such as a single control layer. The insulating layer between the various gates is for isolation. Likewise, the edge one of the composite gate structures is connected to a selection transistor with the select gate 314, gate dielectric layer 413, S/D regions 414, 416, while the other edge one of the composite gate structures is connected to a selection transistor with the select gate 420, gate dielectric layer 421, S/D regions 422, 424. As previous description, FIG. 5B shows the schematic semiconductor structure for the alternative situation in omitting one selection transistor. The S/D region 424 is directly coupled to a power terminal VS.

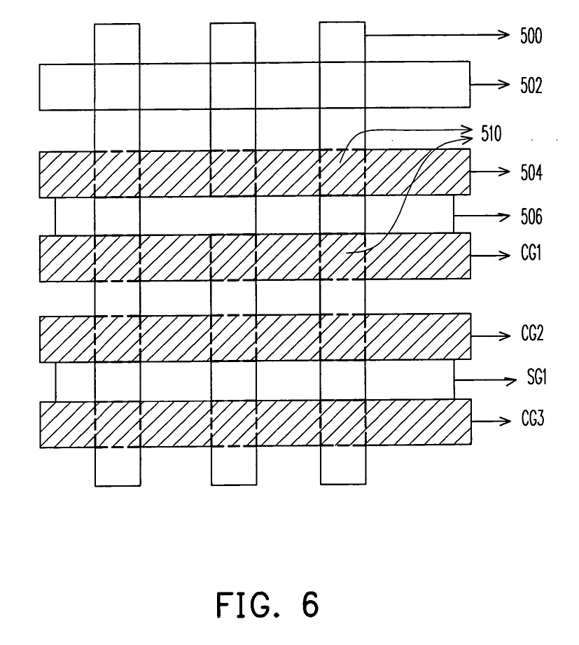

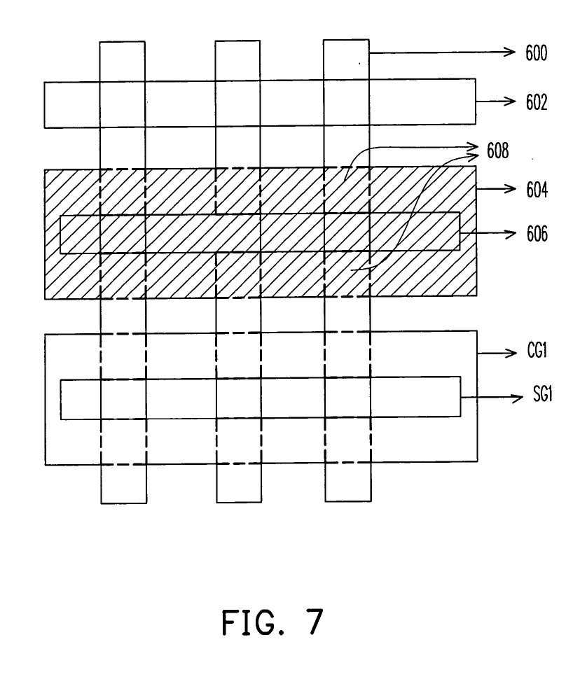

FIGS. 6 and 7 are top-view drawings, schematically illustrating a layout of the nonvolatile memory devices as shown in FIG. 4A and FIG. 5A. Here, only a portion of the full memory array is shown. In FIG. 4A and FIG. 6, the cross-sectional view of the NAND bit line 500 is shown in FIG. 4A. The select gate 314 in FIG. 4A is equivalent to the select gate line 502. The composite gate structure includes two storage gate structure lines 504 and a select gate line 506. The charge storage layer at the regions 510 serve as the memory bit cells. In FIG. 5A and FIG. 7, the cross-sectional view of the NAND bit line 600 is shown in FIG. 5A. The select gate 314 in FIG. 5A is equivalent to the select gate line 602. The composite gate structure includes one storage gate structure line 604 with two storage gate structures and a select gate line 606. The charge storage layer at the regions 608 serve as the memory bit cells. The storage gate structure line 604 is indicated by CG1 while the select gate line 606 is indicated by SG1, in FIG. 5A.

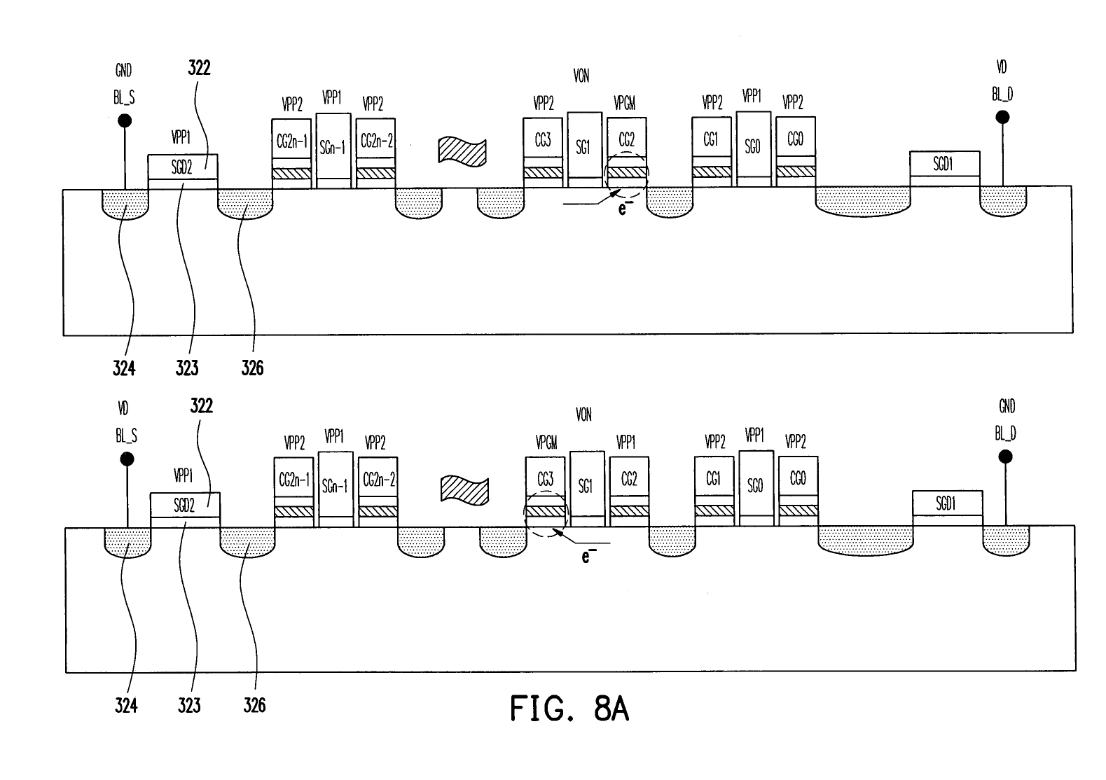

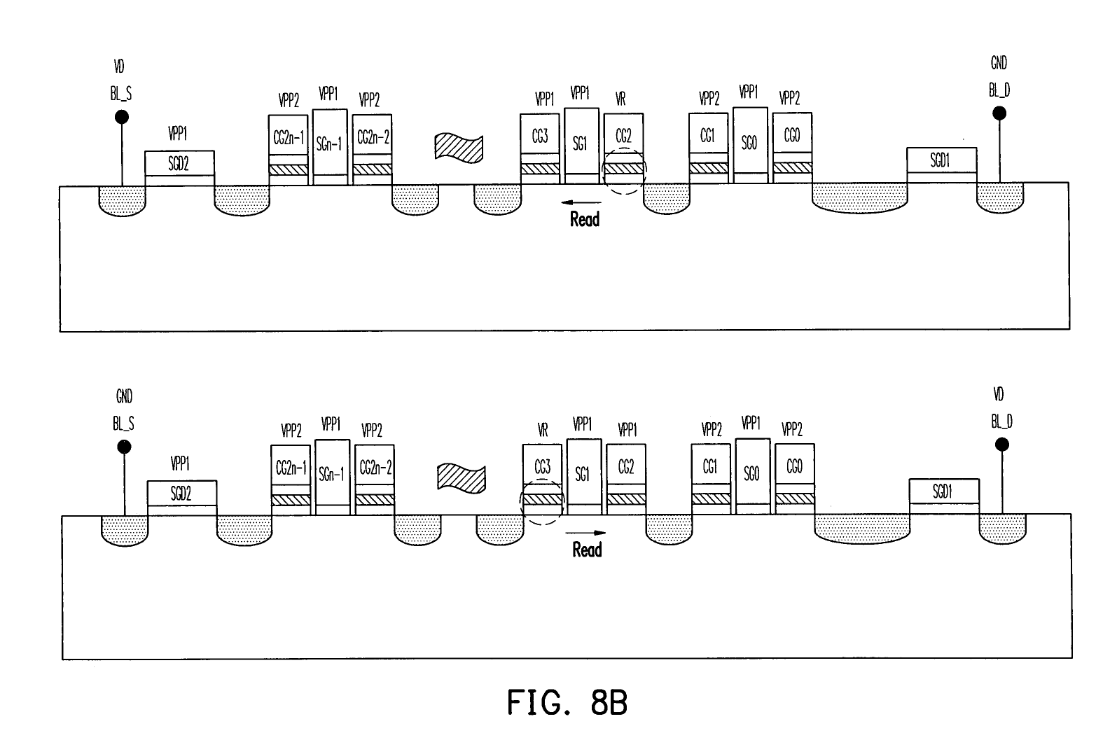

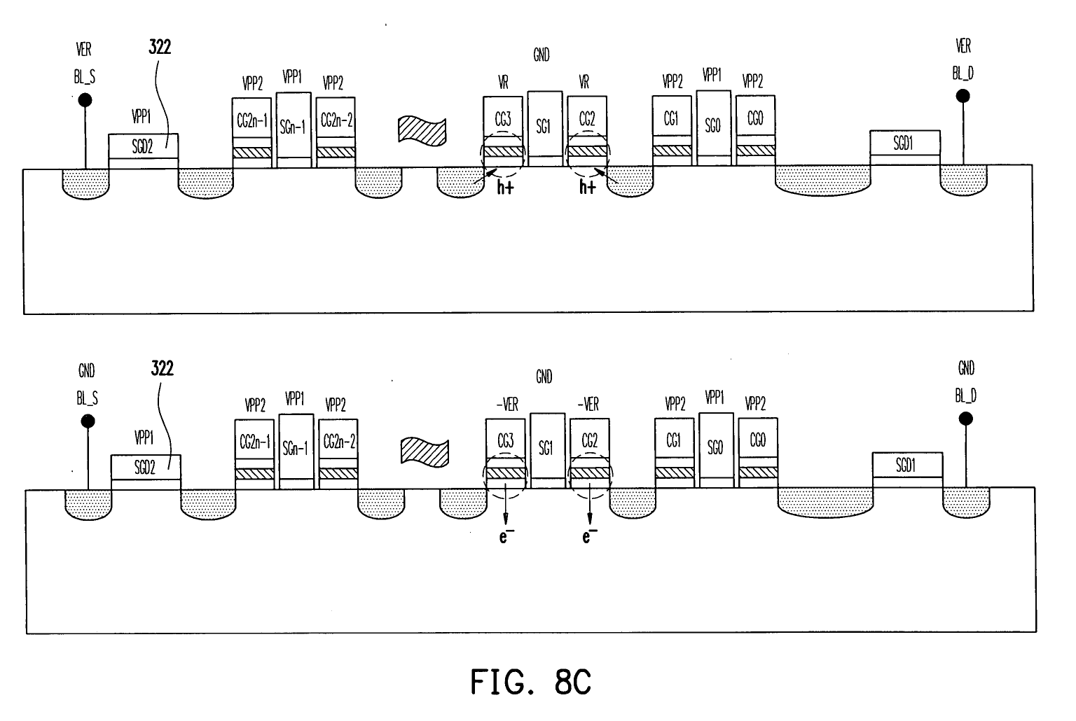

Now, operations of the memory device are, for example, described as follows. FIG. 8A is the drawing, schematically illustrating the program operations, according to the embodiment of the invention. Taking the structure in FIG. 2 and FIG. 4A as the example for descriptions, if the right bit cell of the composite gate structure with select gate SG1 is intended to be programmed, shown in upper drawing, the drain voltage VD is applied to the bit line terminal BL_D while the source voltage, such as ground voltage, is applied to the bit line terminal BL-S (or VS). The control gate line CG2 is applied with a program voltage VPGM, the select gate line is applied with a turning-on voltage VON, the other control gate lines are applied with a voltage VPP2. The select gate lines are applied with a voltage VPP1. The voltages VPP1 and VPP2 are used to cause underneath region of the substrate to be changed to performing the function of channel, so that the source voltage and the drain voltage can be passed to the S/D regions beside the control gate CG2 having the program voltage VPGM. As a result, for example, the electrons are trapped into charge trapping layer under the corresponding control gate CG2. Alternatively, if the left bit cell is to be programmed, as shown in lower drawing, the mechanism is similar but the current direction caused by the source voltage (GND) and the drain voltage (VD) are reversed. The control gate line CG3 is applied with the program voltage VPGM.

FIG. 8B is the drawing, schematically illustrating the read operations, according to the embodiment of the invention. In FIG. 8B, the read operation is shown. If the right bit cell is to be read, shown in upper drawing, the bit line terminal BL_S (or VS) is applied with the voltage VD while the bit line terminal BL_D is applied with the ground voltage GND. The control gate line CG2 is applied with a reads voltage VR, with the other gates are applied the voltage BPP1 or VPP2 for passing the source voltage and the drain voltage to the S/D regions beside the control gate line CG2. The read direction with respect to electrons is indicated by arrow. Alternatively, if the left bit cell under the control gate line CG3 is to be read, shown in lower drawing, the voltages are arranged in reverse direction. The voltage VD is applied to the bit line terminal BL_D while the ground voltage is applied to the bit line terminal BL_S (or VS).

FIG. 8C is the drawing, schematically illustrating the erase operations, according to the embodiment of the invention. In FIG. 8C, if the memory is to be erased, it usually has two mechanisms based on the mechanism of band to band hot hole erase, or FN erase. For the band to band hot hole erase, it is shown in upper drawing, both the bit line terminals BL_D and BL_S (VS) are applied with the erase voltage VER, while the selection gate SG1 is applied with a ground voltage GND and the control gate line is applied with a voltage, such as the voltage VR. As a result, the hot holes h+ are driven into the charge trapping layer to neutralize the electrons. Alternatively, based on the FN erase shown in lower drawing, both the bit line terminals BL_D and BL_S (VS) are applied with the ground voltage GND. The control gate lines CG2 and CG3 are applied with a negative voltage, such as −VER, so as to drive the trapped electrons into the substrate. The substrate is applied with a relative positive voltage to allow the electrons to flow into the substrate and then to the ground terminals.

It should be noted that, the operation voltages for programming, reading and erasing can be changed, and are not limited to the foregoing examples. The operation voltages can be properly set, based on the structure of the invention.

Further, if the memory cell structure is taking the structure in FIG. 5A, then it is shown in FIG. 3. The access mechanism is the same but the control gate line CG2 and CG3 in FIG. 2 can be treated as a same voltage of VPGM or VR in FIG. 8A and FIG. 8B. Both the control gate are applied with the same voltage, it can simplify the operation. However, it may be a little higher error rate in accessing cell.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A structure of a nonvolatile memory device, comprising:
a plurality of composite gate structures formed on a substrate as a string along a bit line (BL) direction, wherein each of the composite gate structures comprises a first storage gate structure, a second storage gate structure, a selection gate structure between the two storage gate structures, wherein each of the storage gate structures corresponds to a memory bit cell;
a plurality of doped regions in the substrate between the composite gate structures;
a first selection doped region, formed in the substrate, coupled between a first BL connection terminal and a first edge one of the composite gate structures; and
a second selection doped region, formed in the substrate, coupled between a second BL connection terminal and a second edge one of the composite gate structures,
wherein each of the storage gate structures of the composite gate structures includes a charge storage layer over the substrate and a control gate over the charge storage layer.

2. The structure of claim 1, wherein the two control gates of the two storage gate structures are structurally separated at both sides of the selection gate.

3. The structure of claim 1, wherein the two control gates of the two storage gate structures together are an integrated gate layer also over the selection gate, so that the two control gates are electrically connected.

4. The structure of claim 1, wherein each of the charge storage layers comprises nitride, Si rich SiN, tantalum oxide (Ta₂O₅), aluminum oxide (Al₂O₃), or nano-crystal Silicon.

5. The structure of claim 1, wherein the charge storage layer is a stacked layer, comprising a bottom oxide layer, a top oxide layer and a middle charge trapping layer between the bottom oxide layer and the top oxide layer.

6. The structure of claim 1, further comprising:
a first source/drain (S/D) selection transistor, coupled to a first edge one of the composite gate structures; and
a second S/D selection transistor, coupled to a second edge one of the composite gate structures,
wherein the first S/D selection transistor and the second S/D selection transistor respectively pass a source voltage and a drain voltage to a selected one of the composite gate structures, so as to access a corresponding one of the memory bit cells.

7. The structure of claim 1, further comprising:
a source/drain (S/D) selection transistor, coupled to a first edge one of the composite gate structures; and
a doped S/D region, coupled to a second edge one of the composite gate structures, without coupling to additional selection transistor.
wherein the S/D selection transistor and the doped S/D region respectively pass a source voltage and a drain voltage to a selected one of the composite gate structures, so as to access a corresponding one of the memory bit cells.

8. The structure of claim 6, wherein is a current direction caused by the source voltage and the drain voltage determines the corresponding one of the memory bit cells being accessed.

9. The structure of claim 7, wherein is a current direction caused by the source voltage and the drain voltage determines the corresponding one of the memory bit cells being accessed.

10. A semiconductor structure of dual-bit memory cell, comprising:
a first storage gate structure over a substrate;
a second storage gate structure over the substrate;
a selection gate over the substrate between the first and the second storage gate structures;
a first doped region, in the substrate at an outer side of the first storage gate structure; and
a second doped region, in the substrate at an outer side of the second storage gate structure,
wherein the first storage gate structure and the second storage gate structure are a stack gate structure including a charge storage layer and a control gate over the charge storage layer.

11. The semiconductor structure of claim 10, wherein the control gates of the first storage gate structure and the second storage gate structure are structurally separated.

12. The semiconductor structure of claim 10, wherein the control gates of the first storage gate structure and the second storage gate structure are structurally connected as a single structural layer.

13. The semiconductor structure of claim 10, wherein the charge storage layer comprises nitride, Si rich SiN, tantalum oxide (Ta₂O₅), aluminum oxide (Al₂O₃), or nano-crystal Silicon.

14. The semiconductor structure of claim 10, wherein the charge storage layer is a stacked layer, comprising a bottom oxide layer, a top oxide layer and a middle charge trapping layer between the bottom oxide layer and the top oxide layer.

15. An operation method of a nonvolatile memory device as recited in claim 1, comprising:
applying a set of reading voltages on the composite gate structures, the first selection doped region and the second selection doped region, for a read operation on a selected reading cell;
applying a set of programming voltages on the composite gate structures, the first selection doped region and the second selection doped region, for a program operation on a selected programming cell; and
applying a set of erasing voltages on the composite gate structures, the first selection doped region and the second selection doped region, for an erase operation on a selected erasing cell.

16. The operation method of claim 15, wherein in the set of programming voltages in the program operation, the selection gate of the selected programming cell is applied with a voltage greater than a threshold voltage, so as to constrain a programming current to flow through the selected programming cell in a corresponding one of the composite gate structures.

17. The operation method of claim 15, wherein desired voltages for S/D voltages are applied at the first selection doped region and the second selection doped region, and are passed to the selected programming cell, the selected reading cell, or the selected erasing cell.

18. The operation method of claim 15, wherein in the erase operation, all information stored in an array block of the memory bit cells is erased at the same time.

19. The operation method of claim 15, wherein the two control gates of the two storage gate structures are structurally separated at both sides of the selection gate, and are applied with different voltage levels.

20. The operation method of claim 15, wherein the two control gates of the two storage gate structures together are an integrated gate layer also over the selection gate, so that the two control gates are electrically connected, and are therefore applied with a same voltage level.
